(19) United States
(12) Patent Application Publication
(10) Pub. No.: US 2013/0001679 A1
(43) Pub. Date: Jan. 3, 2013

(54) SEMICONDUCTOR DEVICE AND MANUFACTURING METHOD THEREOF

(75) Inventor: Kengo OMORI, Kyoto (JP)

(73) Assignee: ROHM CO., LTD., Kyoto (JP)

(21) Appl. No.: 13/538,282

(22) Filed: Jun. 29, 2012

(30) Foreign Application Priority Data
Jun. 30, 2011 (JP) 2011-145406

(51) Int. Cl. H01L 29/78; H01L 21/283

(52) U.S. Cl. 257/330; 438/586; 257/E29.262; 257/E21.19

(57) ABSTRACT

A semiconductor device includes a semiconductor layer, a gate trench formed in the semiconductor layer, a source region exposed at a front surface of the semiconductor layer and forming a curved portion of the gate trench, a channel region forming a planar portion of the gate trench, a drain region forming a bottom surface of the gate trench, a gate oxide film formed on an inner surface of the gate trench, a gate electrode embedded inside the gate trench in the planar portion, an embedding insulator film embedded inside the gate trench in the curved portion, a contact trench formed in the semiconductor layer in self-alignment with the curved portion of the gate trench, and a channel contact region formed on a bottom surface of the contact trench.

### CROSS-REFERENCE TO RELATED APPLICATION(S)

This application is based upon and claims the benefit of priority from Japanese Patent Application No. 2011-145406, filed on Jun. 30, 2011, the entire contents of which are incorporated herein by reference.

### TECHNICAL FIELD

The present disclosure relates to a semiconductor device provided with a trench gate type MOSFET and a manufacturing method thereof

### BACKGROUND

There are conventionally known methods of forming a body contact layer of a trench gate type MOSFET. For example, there is known a method that includes the steps of forming a trench in a substrate; forming a gate insulator film on the inner wall of the trench by thermal oxidation, embedding a polysilicon layer inside the gate insulator film formed in the trench; forming a second base layer and a source region in the substrate; forming an ion injection layer by injecting As (arsenic) ions into the upper surface of the polysilicon layer formed inside the trench, and consequently, amorphizing the upper end portion of the polysilicon layer; transforming the ion injection layer into an interlayer insulator film (LOCOS insulator film) by thermal oxidation; forming a self-aligning groove through a self-alignment process using the interlayer insulator film as a mask; and forming, on the bottom surface of the self-aligning groove, a body contact layer connected to the second base layer.

### SUMMARY

According to one aspect of the present disclosure, there is provided a semiconductor device, including: a semiconductor layer having a front surface and a rear surface; a gate trench formed in the semiconductor layer, the gate trench including an open end, a curved portion formed at the open end to have an opening width growing larger like a trumpet toward the front surface of the semiconductor layer, and a planar portion formed closer to the rear surface of the semiconductor layer with respect to the curved portion to have a constant opening width; a first-conductivity-type source region exposed at the front surface of the semiconductor layer and configured to form the curved portion of the gate trench; a second-conductivity-type channel region formed closer to the rear surface of the semiconductor layer with respect to the source region to adjoin to the source region and configured to form the planar portion of the gate trench; a first-conductivity-type drain region formed closer to the rear surface of the semiconductor layer with respect to the channel region to adjoin to the channel region and configured to form a bottom surface of the gate trench; a gate oxide film formed on an inner surface of the gate trench; a gate electrode embedded inside the gate trench in the planar portion of the gate trench; an embedding insulator film embedded inside the gate trench in the curved portion of the gate trench; a contact trench formed in the semiconductor layer in self-alignment with the curved portion of the gate trench, the contact trench extending through the source region and having a deepest portion reaching the channel region; and a second-conductivity-type channel contact region formed on a bottom surface of the contact trench.

With the contact trench extending to the channel region through the source region formed in self-alignment with the curved portion of the gate trench, and the channel contact region formed on the bottom surface of the contact trench, it is possible to expose the source region on a portion of the side surface of the contact trench. The contact trench is formed on the entire surface of the semiconductor layer excluding the region in which the embedding insulator film is formed. Thus, the contact trench can make contact with the channel region over an increased area while maintaining contact with the source region. As a result, it is possible to reduce the contact resistance with respect to the channel region, thereby reducing channel resistance. This may prevent the turning-on of the p-n junction formed between the channel region and the source region and the turning-on of the parasitic bipolar transistor arranged inside the semiconductor device. Accordingly, it is possible to enhance breakdown tolerance.

According to another aspect of the present disclosure, there is provided a semiconductor device manufacturing method, including: a step of providing a semiconductor layer having a front surface and a rear surface; a step of forming a hard mask on the front surface of the semiconductor layer, the semiconductor layer including a first-conductivity-type source region exposed at the front surface of the semiconductor layer, a second-conductivity-type channel region formed closer to the rear surface of the semiconductor layer with respect to the source region to adjoin to the source region and a first-conductivity-type drain region formed closer to the rear surface of the semiconductor layer with respect to the channel region to adjoin to the channel region; a step of forming a gate trench by etching the semiconductor layer using the hard mask, the gate trench extending through the source region and the channel region and having a deepest portion reaching the drain region; a step of forming a gate oxide film on an inner surface of the gate trench; a step of forming a gate electrode so as to expose a portion of the gate oxide film by embedding an electrode material inside the gate trench to reach at least an upper end of the channel region in a thickness direction of the gate trench; a step of forming a curved portion at an open end of the gate trench to have an opening width growing larger like a trumpet toward the front surface of the semiconductor layer and simultaneously forming a planar portion closer to the rear surface of the semiconductor layer with respect to the curved portion to have a constant opening width by subjecting the semiconductor layer to thermal oxidation and oxidizing the exposed portion of the gate oxide film in a state where the front surface of the semiconductor layer is covered with the hard mask; a step of forming an embedding insulator film in the curved portion of the gate trench by embedding an insulating material inside the gate trench; a step of forming a contact trench in the semiconductor layer in self-alignment with the curved portion of the gate trench by etching the semiconductor layer using the embedding insulator film as a mask, the contact trench extending through the source region and having a deepest portion reaching the channel region; and a step of forming a channel contact region in the channel region by injecting second-conductivity-type ions into a bottom surface of the contact trench.

With this method, thermal oxidation is performed in a state where the front surface of the semiconductor layer is covered with the hard mask (etching mask) used for the formation of the gate trench and a portion of the gate oxide film is covered with the gate electrode. Consequently, a portion of the inner surface of the gate trench (to become the curved portion) is partially oxidized while preventing the front surface of the semiconductor layer and a portion of the gate oxide film from making contact with oxygen (O₂) and water vapor (H₂O) and restraining oxidization of the covered portions. Thus, it is possible to oxidize the exposed portion of the gate oxide film not covered with the gate electrode and to widen the open end of the gate trench in a trumpet shape. Further, the embedding insulator film is embedded in the trumpet-shaped curved portion of the gate trench. By performing etching with the embedding insulator film used as a mask, the contact trench can be formed in self-alignment with the curved portion of the gate trench. Accordingly, even if the pitch of the gate trench is minute, there is no need to maintain alignment accuracy when forming the contact trench. This makes it possible to form the contact trench more easily.

When performing the thermal oxidation, the portion of the gate oxide film contiguous to the channel region is covered with the gate electrode. It is therefore possible to prevent the channel region from making contact with oxygen (O₂) and water vapor (H₂O). Thus, the thickness of the portion of the gate oxide film facing toward the channel region can be kept unchanged. As a result, characteristics such as a threshold voltage and the like can be obtained as designed, making it possible to manufacture a highly reliable semiconductor device.

In one embodiment, the portion of the gate oxide film formed in the curved portion is two to four times as thick as the portion of the gate oxide film formed in the planar portion. In addition, the opening width of the curved portion of the gate trench can be widened to a suitable size by performing thermal oxidation so that the thickness of the portion of the gate oxide film formed in the curved portion of the gate trench can fall within the range noted above.

In one embodiment, the alignment error of the contact trench with respect to the gate trench is 0.1 μm or less. In addition, with the present disclosure, it is possible to easily form the contact trench having a minute opening width of from 0.2 μm to 0.5 μm. Further, the semiconductor layer may be formed of a silicon semiconductor layer.

In one embodiment, the step of forming the gate electrode includes: a step of depositing the electrode material to fill the gate trench with the electrode material; and a step of exposing a portion of the gate oxide film by etching and leveling down an upper surface of the deposited electrode material. With this method, the exposed extent of the gate oxide film can be set more easily by controlling the etching amount of the electrode material, making it possible to readily decide the widening extent of the opening width of the gate trench (namely, the forming extent of the curved portion formed by thermal oxidation).

In one embodiment, the step of forming the embedding insulator film includes: a step of depositing the insulating material until at least the front surface of the semiconductor layer is concealed; and a step of etching back the deposited insulating material until the front surface of the semiconductor layer is exposed. With this method, the region of the semiconductor layer to be formed with the contact trench is exposed by etch-back, making it possible to omit troublesome steps, such as a patterning step, which would otherwise need to be performed to define the region stated above.

In one embodiment, the step of forming the hard mask includes a step of forming a two-layer film composed of a SiO₂ film and a SiN film by first forming the SiO₂ film and then forming the SiN film on the SiO₂ film.

### BRIEF DESCRIPTION OF THE DRAWINGS

FIG. 1 is a schematic plan view of a trench gate type MOS transistor according to an embodiment of the present disclosure.

FIG. 2 is a bird's-eye section view of the trench gate type MOS transistor shown in FIG. 1, illustrating a cross section taken along line A-A in FIG. 1.

FIG. 3A is a view showing a step of a manufacturing process of the trench gate type MOS transistor shown in FIG. 2.

FIG. 3B is a view showing a step subsequent to the step shown in FIG. 3A.

FIG. 3C is a view showing a step subsequent to the step shown in FIG. 3B.

FIG. 3D is a view showing a step subsequent to the step shown in FIG. 3C.

FIG. 3E is a view showing a step subsequent to the step shown in FIG. 3D.

FIG. 3F is a view showing a step subsequent to the step shown in FIG. 3E.

FIG. 3G is a view showing a step subsequent to the step shown in FIG. 3F.

FIG. 3H is a view showing a step subsequent to the step shown in FIG. 3G.

FIG. 3I is a view showing a step subsequent to the step shown in FIG. 3H.

FIG. 3J is a view showing a step subsequent to the step shown in FIG. 3I.

FIG. 4 is a view showing a first modified example of the arrangement of unit cells of the trench gate type MOS transistor shown in FIG. 1.

FIG. 5 is a view showing a second modified example of the arrangement of unit cells of the trench gate type MOS transistor shown in FIG. 1.

### DETAILED DESCRIPTION

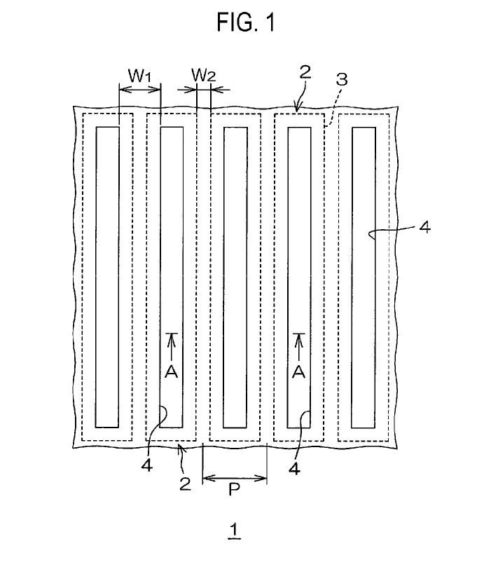

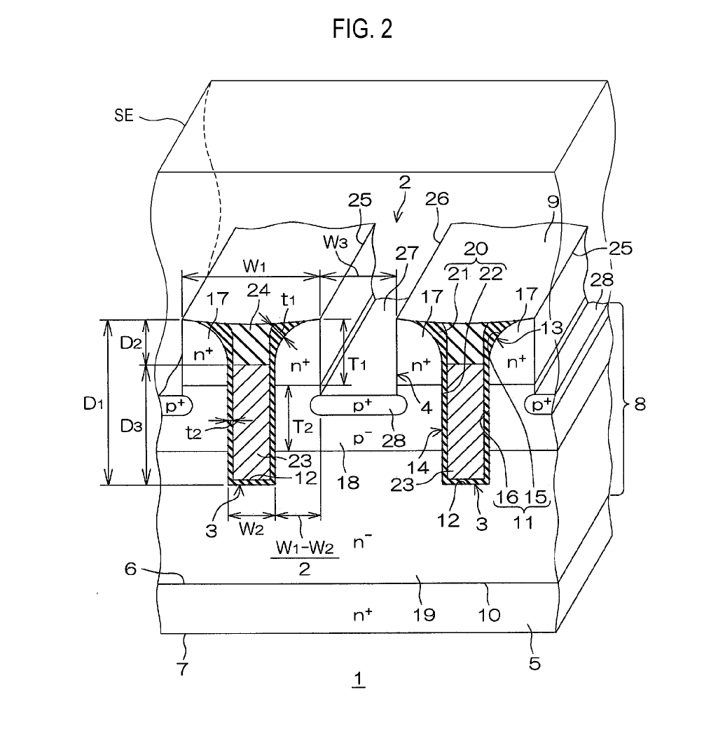

Certain embodiments of the present disclosure will now be described in detail with reference to the accompanying drawings. FIG. 1 is a schematic plan view of a trench gate type MOS transistor according to an embodiment of the present disclosure. FIG. 2 is a bird's-eye section view of the trench gate type MOS transistor shown in FIG. 1, illustrating a cross section taken along line A-A in FIG. 1. Referring to FIG. 1, a MOS transistor 1 is a trench gate type MOSFET (Metal Oxide Semiconductor Field Effect Transistor) and includes a plurality of stripe-shaped unit cells 2 arranged parallel to one another. The respective unit cells 2 are divided by stripe-shaped gate trenches 3. The spacing (pitch P) between the gate trenches 3 adjoining to each other is, e.g., from 0.9 μm to 1.5 μm. An elongated contact trench 4 having a rectangular shape when viewed in a plan view is formed in each of the unit cells 2. The elongated contact trench 4 extends from one longitudinal end to the other longitudinal end of the corresponding unit cell 2.

Referring next to FIG. 2, the MOS transistor 1 includes an n⁺ type silicon substrate 5 (having an impurity concentration of, e.g., from 1×10¹⁹ to 5×10¹⁹ cm⁻³). The silicon substrate 5 serves as a drain of the MOS transistor 1. Examples of the n type impurity include phosphorus (P) and arsenic (As). An n⁺ type silicon epitaxial layer 8 (having an impurity concentration of, e.g., from 1×10¹⁶ to 5×10¹⁵ cm⁻³) lower in impurity concentration than the silicon substrate 5 is formed on a front surface (upper surface) 6 of the silicon substrate 5. The thickness of the silicon epitaxial layer 8 as a semiconductor layer is, e.g., from 3 μm to 10 μm.

In the silicon epitaxial layer 8, the gate trenches 3 each having side surfaces 11 and a bottom surface 12 are formed in a stripe shape. The gate trenches 3 are dug down from the front surface 9 of the silicon epitaxial layer 8 toward the silicon substrate 5. Thus, a plurality of the stripe-shaped unit cells 2 divided by the side surfaces 11 of the gate trenches 3 is formed in the silicon epitaxial layer 8. Each of the gate trenches 3 includes a curved portion 13 formed at the open end side thereof The opening width W₁ of the curved portion 13 continuously increases toward the front surface 9 of the silicon epitaxial layer 8 in a trumpet-like fashion when seen from a section view. Each of the gate trenches 3 further includes a planar portion 14 formed at the direction of the rear surface 10 of the silicon epitaxial layer 8 with respect to the curved portion 13. The opening width W₂ of the planar portion 14 is constant.

The curved portion 13 of each of the gate trenches 3 has curved surfaces (side surfaces 15) so that the upper portion of each of the unit cells 2 (a portion of a source region 17 to be described later) divided by the curved portion 13 can be formed into a dome shape (hemispherical shape) bulging toward the front surface 9 of the silicon epitaxial layer 8 with a gradually reducing width. The planar portion 14 of each of the gate trenches 3 has mutually-facing parallel planar surfaces (side surfaces 16) contiguous to the lower ends of the side surfaces 15 (curved surfaces) of the curved portion 13.

The spacing (opening width W₂) between the parallel side surfaces 16 of the planar portion 14 is, e.g., from 0.18 μm to 0.5 μm. On the other hand, the spacing (opening width W₁) between the side surfaces 15 of the curved portion 13 contiguous to the side surfaces 16 of the planar portion 14 has a lower limit value (measured between the lower end positions of the side surfaces 15) of, e.g., from 0.18 μm to 0.5 μm, and an upper limit value (measured at the position of the front surface 9 of the silicon epitaxial layer 8) of, e.g., 0.38 μm to 0.7 μm. The spacing (opening width W₁) between the side surfaces 15 of the curved portion 13 continuously increases from the lower limit value to the upper limit value.

The depth D₁ of each of the gate trenches 3 measured from the front surface 9 of the silicon epitaxial layer 8 is, e.g., from 1.0 μm to 1.5 μm. The depth D₂ of the curved portion 13 may be appropriately set depending on the depth of the source region 17 or a channel region 18 to be described later and is, e.g., from 0.2 μm to 0.4 μm. The depth D₃ of the planar portion 14 is, e.g., from 0.8 μm to 0.6 μm.

In the silicon epitaxial layer 8, the n⁺ type source region 17 and the p⁻ type channel region 18 (having an impurity concentration of, e.g., from 1×10¹⁷ to 5×10¹⁷ cm⁻³) are formed in the named order from the front surface 9 of the silicon epitaxial layer 8 around each of the gate trenches 3. A p type impurity, e.g., boron (B) or aluminum (Al), is contained in the channel region 18.

The source region 17 is formed in the surface layer portion of each of the unit cells 2 so that the source region 17 can be exposed on the front surface 9 of the silicon epitaxial layer 8. The source region 17 can form the entirety of the curved portion 13 and an upper portion (a portion) of the planar portion 14 of each of the gate trenches 3. The thickness T₁ of the source region 17 in a direction extending from the front surface 9 toward the silicon substrate 5 is, e.g., from 0.2 μm to 0.4 μm. Unless specifically mentioned otherwise, a thickness defined in the following descriptions means a thickness measured in the direction extending from the front surface 9 of the silicon epitaxial layer 8 toward the silicon substrate 5.

The channel region 18 is formed at the direction of the silicon substrate 5 (at the direction of the rear surface 10 of the silicon epitaxial layer 8) with respect to the source region 17 so that the channel region 18 can adjoin to the source region 17. The thickness T₂ of the channel region 18 is, e.g., from 0.2 μm to 0.4 μm. On the other end, the region of the silicon epitaxial layer 8 existing at the direction of the silicon substrate 5 with respect to the channel region 18 becomes an n⁻ type drain region 19, which is kept in an epitaxially grown state. The drain region 19 exists on the same side of the silicon substrate 5 with respect to the channel region 18 and adjoins to the channel region 18. The drain region 19 forms a lower portion of the planar portion 14 of each of the gate trenches 3 and the bottom surface 12 of each of the gate trenches 3.

A gate oxide film 20 is formed on an inner surface of each of the gate trenches 3 so as to fully cover the inner surface of each of the gate trenches 3. The gate oxide film 20 includes a first portion 21 formed on the side surfaces 15 of the curved portion 13 of each of the gate trenches 3, and a second portion 22 formed on the side surfaces 16 of the planar portion 14 of each of the gate trenches 3. The first portion 21 is two to four times as thick as the second portion 22. For example, the thickness t₁ of the first portion 21 is from 1000 Å to 2000 Å and the thickness t₂ of the second portion 22 is from 350 Å to 600 Å.

In the planar portion 14 of each of the gate trenches 3 (namely, in the portion of each of the gate trenches 3 extending from the bottom surface 12 to a middle portion of the source region 17), polysilicon doped with an n type impurity at a high concentration is embedded inside the gate oxide film 20, thereby forming a gate electrode 23 within each of the gate trenches 3. As a result, there is provided a vertical type MOS transistor 1 in which the source region 17 and the drain region 19 are arranged in a spaced-apart relationship along the vertical direction perpendicular to the front surface 9 of the silicon epitaxial layer 8 with the channel region 18 interposed between the source region 17 and the drain region 19.

In the curved portion 13 of each of the gate trenches 3 (namely, in the portion of each of the gate trenches 3 extending from the middle portion of the source region 17 to the front surface 9 of the silicon epitaxial layer 8), an embedding insulator film 24 made of silicon oxide (SiO₂) is embedded inside the gate oxide film 20. The embedding insulator film 24 is formed so that the upper surface thereof can be flush with the front surface 9 of the silicon epitaxial layer 8. In reality, it is sometimes the case that the certain border shown in FIG. 2 does not exist between the gate oxide film 20 and the embedding insulator film 24. This is because the gate oxide film 20 and the embedding insulator film 24 are made of the same material, SiO₂.

In each of the unit cells 2, the contact trench 4 is formed in self-alignment with the curved portion 13 of each of the gate trenches 3. The contact trench 4 extends through the source region 17 from the front surface 9 of the silicon epitaxial layer 8. The deepest portion of the contact trench 4 reaches the channel region 18. In other words, an opening edge 25 is shared by the contact trench 4 and the gate trench 3. The alignment error of the contact trench 4 with respect to the gate trench 3 is, e.g., 0.01 μm or less.

The opening width W₃ of the contact trench 4 is constant in the thickness direction of the contact trench 4 and is, e.g., from 0.2 μm to 0.5 μm. Since the opening width W₃ of the contact trench 4 sharing the opening edge 25 with the curved portion 13 of the gate trench 3 is constant, the source region 17 having a width equal to one half of a differential value (W₁-W₂), obtained by subtracting the opening width W₂ of the planar portion 14 of the gate trench 3 from the opening width W₁ of the curved portion 13 of the gate trench 3, is necessarily left between a side surface 26 of the contact trench 4 and the side surface 16 of the planar portion 14 of the gate trench 3. The source region 17 is exposed on the side surface 26 of the contact trench 4. In addition, the channel region 18 is exposed on a bottom surface 27 of the contact trench 4.

A p⁺ type channel contact region 28 (having an impurity concentration of, e.g., from 1×10¹⁹ to 1×10² cm⁻³) is formed in the channel region 18 exposed on the bottom surface 27 of the contact trench 4. The channel contact region 28 is linearly formed on the entire bottom surface 27 of the contact trench 4 to extend along the longitudinal direction of the contact trench 4. Further, a source electrode SE is formed on the embedding insulator film 24. The source electrode SE may be connected to all of the unit cells 2 (the source regions 17 and the channel contact regions 28 of the unit cells 2) via a respective contact trench 4. In other words, the source electrode SE may serve as a common wiring line for all of the unit cells 2. A drain electrode (not shown) is formed on a rear surface 7 of the silicon substrate 5 so as to cover the entire area of the rear surface 7. The drain electrode serves as a common electrode for all of the unit cells 2.

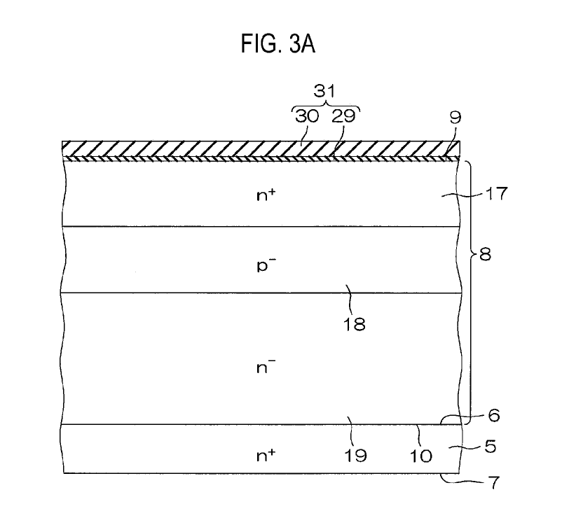

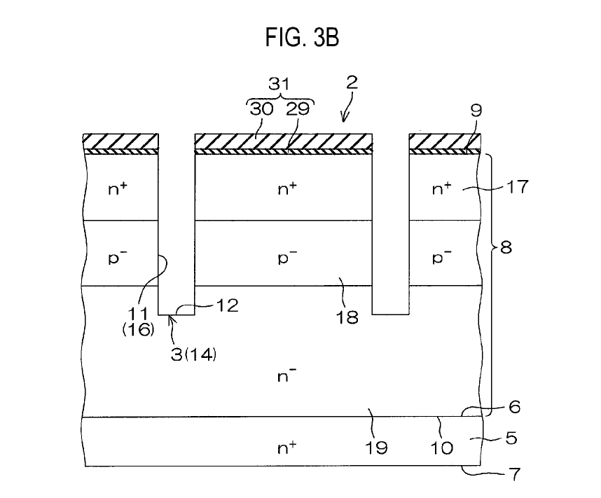

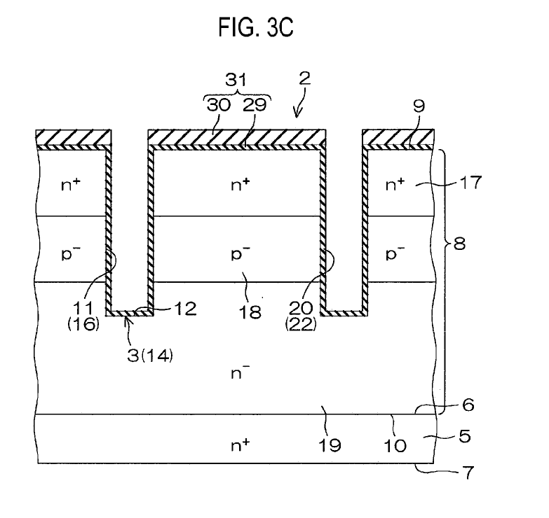

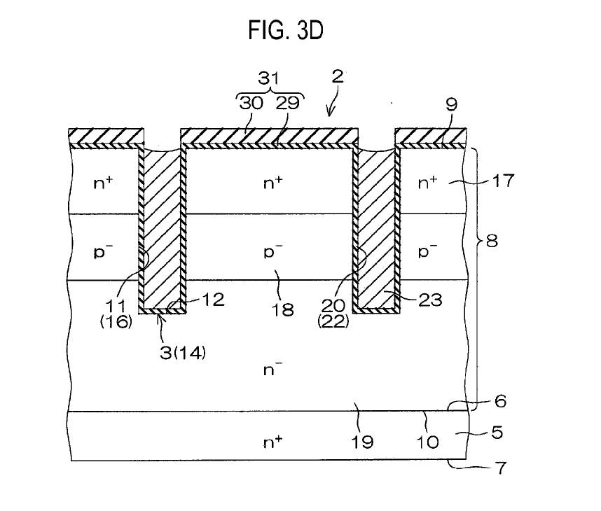

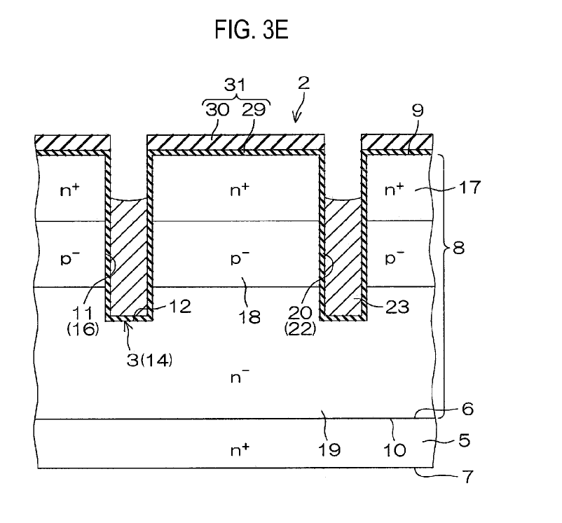

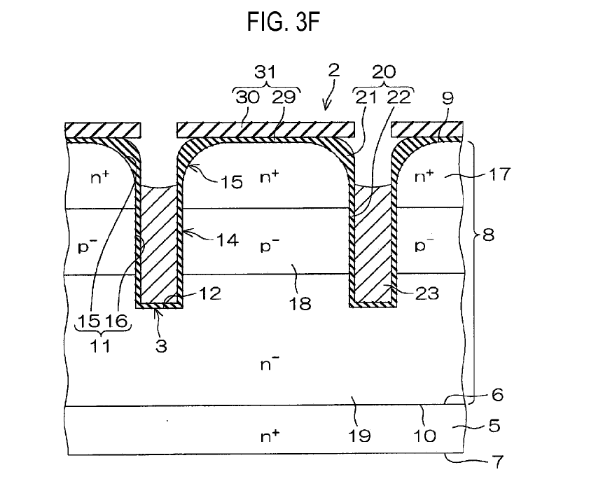

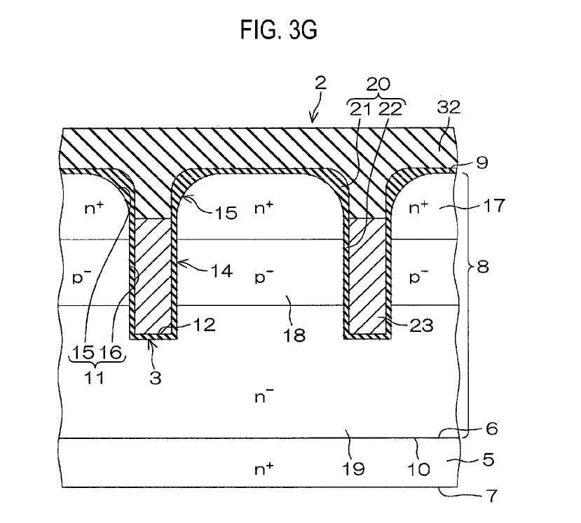

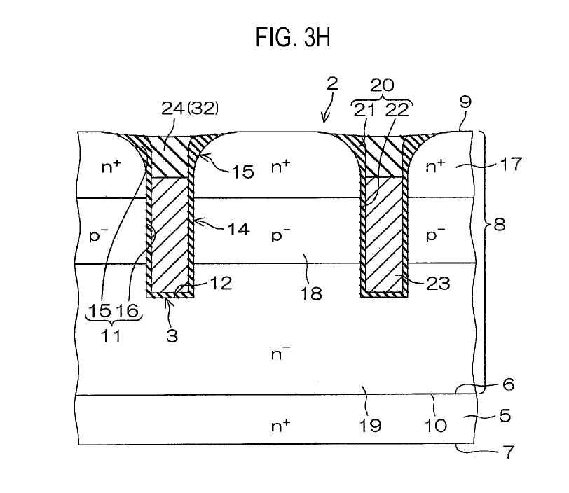

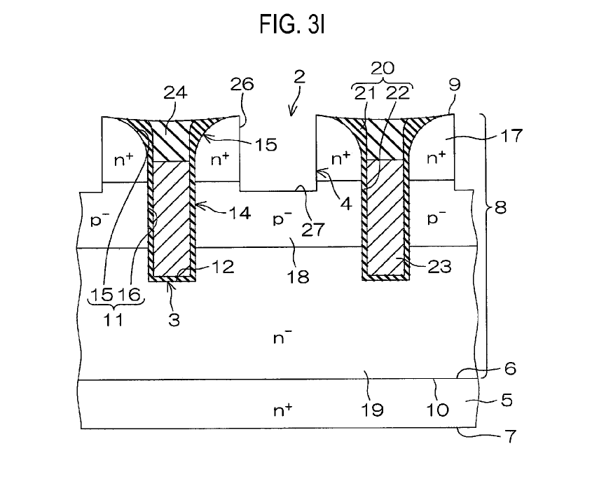

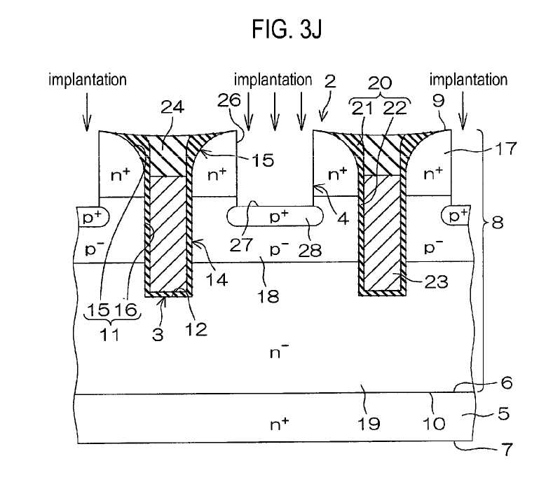

FIGS. 3A through 3J are views showing different steps of a manufacturing process of the trench gate type MOS transistor shown in FIG. 2. FIGS. 3A through 3J show a cross section taken in the same position as FIG. 2. In the manufacture process of the MOS transistor 1, as shown in FIG. 3A, silicon crystals are caused to grow on a front surface 6 of a silicon substrate 5 by an epitaxial growth method such as a CVD (Chemical Vapor Deposition) method, an LPE (Liquid Phase Epitaxy) method, or an MBE (Molecular Beam Epitaxy) method, while doping an n type impurity. Thus an n⁻ type silicon epitaxial layer 8 (drain region 19) is formed on the silicon substrate 5. Then, a p type impurity and an n type impurity are sequentially injected into the front surface 9 of the silicon epitaxial layer 8. After this injection, the injected impurities are activated by annealing (performed, e.g., at a temperature of from 900 degrees C. to 1000 degrees C. for 10 to 30 minutes), thereby simultaneously forming a channel region 18 and a source region 17. Subsequently, by, e.g., a CVD method, a SiO₂ film 29 is formed on the front surface 9 of the silicon epitaxial layer 8 and a SiN film 30 is formed on the SiO₂ film 29, thereby forming a hard mask 31 composed of the SiO₂ film 29 and the SiN film 30. The thickness of the SiO₂ film 29 is, e.g., from 50Å to 100 Å. The thickness of the SiN film 30 is, e.g., from 1000 Å to 1500 Å.

Next, as shown in FIG. 3B, the silicon epitaxial layer 8 is etched through the use of the hard mask 31. Thus, the silicon epitaxial layer 8 is dry-etched from the front surface 9 thereof, thereby forming a gate trench 3 having a planar portion 14. As a consequence, a plurality of unit cells 2 is formed in the silicon epitaxial layer 8.

Next, as shown in FIG. 3C, a gate oxide film 20 having a second portion 22 (with a uniform thickness) is formed on the inner surfaces (side surfaces 11 and a bottom surface 12) of the gate trench 3 by thermal oxidation (performed, e.g., at a temperature of from 850 degrees C. to 950 degrees C. for 10 to 30 minutes).

Next, as shown in FIG. 3D, doped polysilicon (electrode material) is deposited on the silicon epitaxial layer 8 by, e.g., a CVD method. The deposition of polysilicon is continuously performed until at least the front surface 9 of the silicon epitaxial layer 8 becomes concealed. Thereafter, the deposited polysilicon is etched back until the etch-back surface becomes flush with the front surface 9 of the silicon epitaxial layer 8. Consequently, there is formed a gate electrode 23 composed of the polysilicon remaining within the gate trench 3.

Next, as shown in FIG. 3E, an upper surface of the gate electrode 23 is leveled down by, e.g., dry etching, so that a portion of the gate oxide film 20 (the portion to become a first portion 21) can be exposed toward the inside of the gate trench 3.

Next, as shown in FIG. 3F, the silicon epitaxial layer 8 is subjected to thermal oxidation (e.g., at a temperature of from 1000 degrees C. to 1100 degrees C. for 10 to 30 minutes) in a state where the front surface 9 of the silicon epitaxial layer 8 is covered with the hard mask 31. Thus, the exposed portion of the gate oxide film 20 is oxidized, whereby a curved portion 13 having an opening width W1 gradually increasing like a trumpet is formed at the open end of the gate trench 3. At the same time, the portion of the gate oxide film 20 growing thicker in proportion to the degree of oxidization becomes a first portion 21. Thereafter, the hard mask 31 is removed.

Next, as shown in FIG. 3G, SiO₂ 32 (insulating material) is deposited on the silicon epitaxial layer 8 by, e.g., a CVD method. The deposition of SiO₂ 32 is continuously performed until at least the front surface 9 of the silicon epitaxial layer 8 is concealed.

Next, as shown in FIG. 3H, the deposited SiO₂ 32 is etched back until the etch-back surface becomes flush with the front surface 9 of the silicon epitaxial layer 8. Thus, there is formed an embedding insulator film 24 composed of the SiO₂ remaining within the gate trench 3. At the same time, the front surface 9 of the silicon epitaxial layer 8 is exposed between the embedding insulator films 24 adjacent to each other.

Next, as shown in FIG. 3I, the exposed silicon epitaxial layer 8 is etched using the embedding insulator film 24 as a mask. Thus, the silicon epitaxial layer 8 is dry-etched from the front surface 9 thereof, whereby a contact trench 4 is formed in self-alignment with the curved portion 13 of the gate trench 3.

Next, as shown in FIG. 3J, a p type impurity is injected into the contact trench 4 in the thickness direction of the gate trench 3. After this injection, the injected impurity is activated by annealing (performed, e.g., at a temperature of from 900 degrees C. to 950 degrees C. for 0.5 to 1 minute), thereby forming a channel contact region 28.

Subsequently, the MOS transistor 1 shown in FIG. 2 is obtained by forming the source electrode SE and a drain electrode (not shown).

With the embodiment described above, thermal oxidation is performed in a state where the front surface 9 of the silicon epitaxial layer 8 is covered with the hard mask 31 (etching mask) used for the formation of the gate trench 3 and in a state where a portion of the gate oxide film 20 (the portion to become the second portion 22) is covered with the gate electrode 23 (see FIG. 3F). Consequently, a portion of the inner surface of the gate trench 3 (to become the curved portion 13) is partially oxidized while preventing the front surface 9 of the silicon epitaxial layer 8 and a portion of the gate oxide film 20 from making contact with oxygen (O₂) and water vapor (H₂O) and restraining oxidization of the covered portions.

Thus, the curved portion 13 can be formed by oxidizing the exposed portion of the gate oxide film 20 not covered with the gate electrode 23 and widening the open end of the gate trench 3 into a trumpet shape. The embedding insulator film 24 is embedded in the trumpet-shaped curved portion 13 of the gate trench 3. By performing etching with the embedding insulator film 24 used as a mask, the contact trench 4 can be formed in self-alignment with the curved portion 13 of the gate trench 3 (see FIG. 3I).

Accordingly, even if the pitch P of the gate trench 3 is minute, there is no need to make an effort to maintain alignment accuracy when forming the contact trench 4. This makes it possible to form the contact trench 4 more easily. When performing the thermal oxidation shown in FIG. 3F, the portion of the gate oxide film 20 contiguous to the channel region 18 is covered with the gate electrode 23. It is therefore possible to prevent the channel region 18 from making contact with oxygen (O₂) and water vapor (H₂O). Thus the thickness of the second portion 22 of the gate oxide film 20 facing toward the channel region 18 can be kept equal to the thickness available at the time of forming the gate oxide film 20. As a result, the characteristics such as a threshold voltage and the like can be obtained as designed. This makes it possible to manufacture a highly reliable MOS transistor 1.

As shown in FIGS. 3D and 3E, the polysilicon is etched back until the etch-back surface becomes flush with the front surface 9 of the silicon epitaxial layer 8. In addition, the upper surface of the gate electrode 23 is leveled down by dry etching so that a portion of the gate oxide film 20 can be exposed toward the inside of the gate trench 3. Therefore, the exposing extent of the gate oxide film 20 can be set more easily by controlling the etching amount of the polysilicon. This makes it possible to readily decide the widening extent of the opening width of the gate trench 3 (namely, the forming extent of the curved portion 13 formed by thermal oxidation).

As shown in FIG. 3H, the region of the silicon epitaxial layer 8 to be formed with the contact trench 4 is exposed by etch-back. This makes it possible to omit troublesome steps, such as a patterning step, which would otherwise need to be performed to define the region stated above.

With the MOS transistor 1 obtained as above, the contact trench 4 extending to the channel region 18 through the source region 17 is formed in self-alignment with the curved portion 13 of the gate trench 3. The channel contact region 28 is formed on the bottom surface 27 of the contact trench 4.

Accordingly, the source region 17 having a width equal to one half of a differential value (W1-W2) obtained by subtracting the opening width W₂ of the planar portion 14 of the gate trench 3 from the opening width W₁ of the curved portion 13 of the gate trench 3 can be necessarily left between the side surface 26 of the contact trench 4 and the side surface 16 of the planar portion 14 of the gate trench 3. The source region 17 can be exposed on the side surface 26 of the contact trench 4.

The contact trench 4 is formed on the entire surface of the MOS transistor 1 excluding the region in which the embedding insulator film 24 is formed. Thus, the contact trench 4 can make contact with the channel region 18 over an increased area while maintaining contact with the source region 17. As a result, it is possible to reduce the contact resistance with respect to the channel region 18, thereby reducing channel resistance. This makes it difficult to turn on the p-n junction formed between the channel region 18 and the source region 17 and to turn on the parasitic bipolar transistor arranged inside the MOS transistor 1. Accordingly, it is possible to enhance breakdown tolerance.

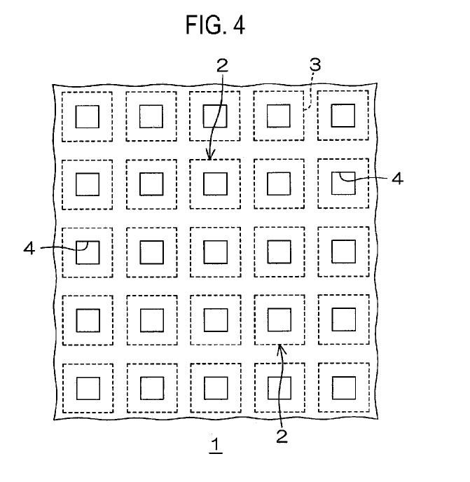

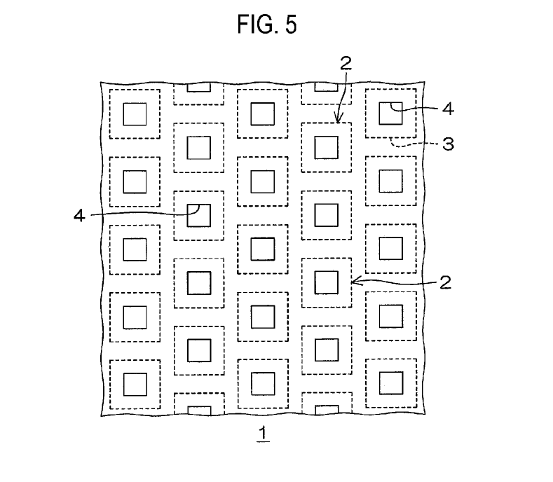

While one embodiment of the present disclosure has been described above, the present disclosure may be embodied in other forms. For example, the arrangement of the unit cells 2 need not be necessarily in a stripe pattern but may be in a matrix pattern as shown in FIG. 4 or in a zigzag pattern as shown in FIG. 5. The shape of each of the unit cells 2 is not limited to a stripe shape (shown in FIG. 1) or a rectangular columnar shape (shown in FIGS. 4 and 5) but may be a polygonal columnar shape such as a triangular columnar shape, a pentagonal columnar shape, or a hexagonal columnar shape.

In the MOS transistor 1, it may be possible to employ a configuration in which the conductivity type of each of the semiconductor portions is inverted. For example, the p type portion may be an n type and the n type portion may be a p type in the MOS transistor 1. It may also be possible to use, e.g., a SiC epitaxial layer, in place of the silicon epitaxial layer 8.

In addition, many different changes in design may be made without departing from the scope of the present disclosure defined in the claims.

While certain embodiments have been described, these embodiments have been presented by way of example only, and are not intended to limit the scope of the disclosures. Indeed, the novel semiconductor devices and manufacturing methods thereof described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device, comprising:
a semiconductor layer having a front surface and a rear surface;
a gate trench formed in the semiconductor layer, the gate trench including an open end, a curved portion formed at the open end to have an opening width growing larger like a trumpet toward the front surface of the semiconductor layer and a planar portion formed closer to the rear surface of the semiconductor layer with respect to the curved portion to have a constant opening width;
a first-conductivity-type source region exposed at the front surface of the semiconductor layer and configured to form the curved portion of the gate trench;
a second-conductivity-type channel region formed closer to the rear surface of the semiconductor layer with respect to the source region to adjoin to the source region and configured to form the planar portion of the gate trench;
a first-conductivity-type drain region formed closer to the rear surface of the semiconductor layer with respect to the channel region to adjoin to the channel region and configured to form a bottom surface of the gate trench;
a gate oxide film formed on an inner surface of the gate trench;
a gate electrode embedded inside the gate trench in the planar portion of the gate trench;
an embedding insulator film embedded inside the gate trench in the curved portion of the gate trench;
a contact trench formed in the semiconductor layer in self-alignment with the curved portion of the gate trench, the contact trench extending through the source region and having a deepest portion reaching the channel region; and
a second-conductivity-type channel contact region formed on a bottom surface of the contact trench.

2. The device of claim 1, wherein the portion of the gate oxide film formed in the curved portion is two to four times as thick as the portion of the gate oxide film formed in the planar portion.

3. The device of claim 1, wherein the alignment error of the contact trench with respect to the gate trench is 0.1 μm or less.

4. The device of claim 1, wherein the contact trench has an opening width of from 0.2 μm to 0.5 μm.

5. The device of claim 1, wherein the semiconductor layer is formed of a silicon semiconductor layer.

6. A semiconductor device manufacturing method, comprising:
providing a semiconductor layer having a front surface and a rear surface;
forming a hard mask on the front surface of the semiconductor layer, the semiconductor layer including a first-conductivity-type source region exposed at the front surface of the semiconductor layer, a second-conductivity-type channel region formed closer to the rear surface of the semiconductor layer with respect to the source region to adjoin to the source region and a first-conductivity-type drain region formed closer to the rear surface of the semiconductor layer with respect to the channel region to adjoin to the channel region;
forming a gate trench by etching the semiconductor layer using the hard mask, the gate trench extending through the source region and the channel region and having a deepest portion reaching the drain region;
forming a gate oxide film on an inner surface of the gate trench;
forming a gate electrode so as to expose a portion of the gate oxide film by embedding an electrode material inside the gate trench to reach at least an upper end of the channel region in a thickness direction of the gate trench;
forming a curved portion at an open end of the gate trench to have an opening width growing larger like a trumpet toward the front surface of the semiconductor layer and simultaneously forming a planar portion closer to the rear surface of the semiconductor layer with respect to the curved portion to have a constant opening width by subjecting the semiconductor layer to thermal oxidation and oxidizing the exposed portion of the gate oxide film in a state where the front surface of the semiconductor layer is covered with the hard mask;
forming an embedding insulator film in the curved portion of the gate trench by embedding an insulating material inside the gate trench;
forming a contact trench in the semiconductor layer in self-alignment with the curved portion of the gate trench by etching the semiconductor layer using the embedding insulator film as a mask, the contact trench extending through the source region and having a deepest portion reaching the channel region; and
forming a channel contact region in the channel region by injecting second-conductivity-type ions into a bottom surface of the contact trench.

7. The method of claim 6, wherein forming the gate electrode comprises:
depositing the electrode material to fill the gate trench with the electrode material; and
exposing a portion of the gate oxide film by etching and leveling down an upper surface of the deposited electrode material.

8. The method of claim 6, wherein forming the embedding insulator film comprises:
depositing the insulating material until at least the front surface of the semiconductor layer is concealed; and
etching back the deposited insulating material until the front surface of the semiconductor layer is exposed.

9. The method of claim 6, wherein forming the hard mask comprises forming a two-layer film composed of a SiO₂ film and a SiN film by first forming the SiO₂ film and then forming the SiN film on the SiO₂ film.
